(19) United States
(12) Patent Application Publication
(10) Pub. No.: US 2006/0081182 A1
(43) Pub. Date: Apr. 20, 2006

(54) Method of cleaning thin film deposition system, thin film deposition system and program

(75) Inventors: Mitsuhiro Okada, Tokyo-To (JP); Atsushi Endo, Tokyo-To (JP); Toshiharu Nishimura, Tokyo-To (JP); Kazuhide Hasebe, Tokyo-To (JP)

Correspondence Address: SMITH, GAMBRELL & RUSSELL, LLP, 1850 M STREET, N.W., SUITE 800, WASHINGTON, DC, 20036, US

(73) Assignee: Tokyo Electron Limited

(21) Appl. No.: 11/246,290

(22) Filed: Oct. 11, 2005

(30) Foreign Application Priority Data
Oct. 15, 2004 (JP) 2004-302044

(51) Int. Cl. C23C 16/00; B08B 3/12; B44C 1/22; B05C 11/00

(52) U.S. Cl. 118/715; 118/697; 134/1; 216/63

(57) ABSTRACT

A thin film deposition system cleaning method is capable of efficiently removing reaction products deposited on surfaces of component members of a thin film deposition system. A thermal processing system 1 capable of carrying out the thin film deposition system cleaning method includes a controller 100. The controller 100 controls a heating means so as to heat the interior of a reaction tube 2 at a temperature in the range of 400° C. to 700° C. The controller 100 controls a cleaning gas supply means for supplying a cleaning gas containing fluorine and hydrogen fluoride through a process gas supply pipe 17 into the reaction tube 2 to remove deposits deposited on surfaces exposed to an atmosphere in the reaction tube 2.

### TECHNICAL FIELD

The present invention relates to a method of cleaning a thin film deposition system, a thin film deposition system and a program. More specifically, the present invention relates to a method of cleaning a thin film deposition system to remove deposits deposited on inside surfaces of the thin film deposition system during a deposition process for depositing a thin film on a semiconductor wafer, a thin film deposition system and a program.

### BACKGROUND ART

A semiconductor device fabricating process includes a thin film deposition process for forming a thin film, such as a silicon nitride film, on, for example, semiconductor wafers by a CVD process (chemical vapor deposition process) or the like. The thin film deposition process forms a thin film on semiconductor wafers by the following procedure.

A reaction chamber in a reaction tube of a thin film deposition system, namely, a thermal processing system, is heated at a predetermined loading temperature by a heater and a wafer boat holding a plurality of semiconductor wafers is loaded into the reaction tube. Then, the reaction chamber is heated at a predetermined processing temperature by the heater. Gas is discharged from the reaction tube through an exhaust port to evacuate the reaction chamber at a predetermined pressure. After the predetermined temperature and the predetermined pressure in the reaction tube have been stabilized, source gases are supplied through a process gas supply pipe into the reaction tube. Then, for example, thermal reactions of the source gases take place. Reaction products produced by the thermal reactions deposit on the surfaces of the semiconductor wafers to form a thin film on each of the semiconductor wafers.

The reaction products produced by the thin film deposition process deposit not only on the surfaces of the semiconductor wafers, but also on the inside surface of the reaction tube and the surfaces of jigs and such placed in the reaction tube of the thin film deposition system. If the thin film deposition system is used continuously for the thin film deposition process with the inside surface of the reaction tube and the surfaces of jigs and such coated with the reaction products, the reaction products come off the surfaces and tend to produce particles. The adhesion of the particles to the semiconductor wafers reduces the yield of semiconductor devices.

Therefore, the thin film deposition system is cleaned by a cleaning method after the thin film deposition process has been performed several cycles to remove the deposited reaction products. A cleaning method proposed in JP-A 3-293726 (Patent document 1) supplies a cleaning gas into the reaction tube heated at a predetermined temperature to remove the reaction products deposited on the inside surface of the reaction tube and the surfaces of jigs and such placed in the thin film deposition system.

If the reaction products contain tetraethoxysilane (TEOS), the reaction products deposited on the wall of the reaction tube is removed by a wet cleaning process using a hydrogen fluoride solution (HF solution). The wet cleaning process needs disassembling the thin film deposition system, cleaning the disassembled parts by hand, and assembling and adjusting the thin film deposition system. Thus the thin film deposition system cannot be used for a long time. Consequently, downtime increases and the operating ratio of the thin film deposition system is low.

### DISCLOSURE OF THE INVENTION

The present invention has been made in view of the foregoing problem and it is therefore an object of the present invention to provide a method of cleaning a thin film deposition system, capable of efficiently removing reaction products deposited on surfaces of the component members of the thin film deposition system, a thin film deposition system and a program.

Another object of the present invention is to provide a method of cleaning a thin film deposition system, capable of efficiently removing reaction products deposited on surfaces of the component members of the thin film deposition system and of suppressing the reduction of the operating ratio of the thin film deposition system, a thin film deposition system and a program.

A thin film deposition system cleaning method of cleaning a thin film deposition system to remove deposits adhering to surfaces of the component members of the thin film deposition system after thin films have been deposited on workpieces by supplying process gases into a reaction tube included in the thin film deposition system in a first aspect of the present invention includes a cleaning process including the steps of supplying a cleaning gas containing fluorine and hydrogen fluoride into a reaction chamber defined by the reaction tube and heated at a predetermined temperature, activating the cleaning gas, and removing the deposits by the activated cleaning gas; wherein the deposits contain tetraethoxysilane.

A thin film deposition system cleaning method of cleaning a thin film deposition system to remove deposits adhering to surfaces of the component members of the thin film deposition system after thin films have been deposited on workpieces by supplying process gases into a reaction tube included in the thin film deposition system in a second aspect of the present invention includes a cleaning process including the steps of supplying a cleaning gas containing fluorine and hydrogen fluoride into a reaction chamber defined by the reaction tube and heated at a predetermined temperature, activating the cleaning gas, and removing the deposits by the activated cleaning gas; wherein the a reaction chamber defined by the reaction tube is heated at a temperature in the range of 400° C. to 700° C. during the cleaning process.

Preferably, the reaction chamber is maintained at a pressure in the range of 13.3 Pa to the normal pressure during the cleaning process.

Preferably, component members of the thin film deposition system placed in the reaction chamber are made of quartz.

A thin film deposition system for depositing a thin film on workpieces placed in a reaction chamber by supplying process gases into the reaction chamber, in a third aspect of the present invention includes: a heating means for heating the reaction chamber at a predetermined temperature; a cleaning gas supply means for supplying a cleaning gas containing fluorine and hydrogen fluoride into the reaction chamber; and a control means for controlling the component devises of the thin film deposition system; wherein the control means controls the heating means so as to heat the reaction chamber at a predetermined temperature and controls the cleaning gas supply means so as to supply the cleaning gas into the reaction chamber after the reaction chamber has been heated at the predetermined temperature by the heating means so that the cleaning gas is activated to remove deposits containing tetraethoxysilane and deposited on the inside surface of a reaction tube defining the reaction chamber by the activated cleaning gas.

A thin film deposition system for depositing a thin film on workpieces contained in a reaction chamber by supplying process gases into the reaction chamber, in a fourth aspect of the present invention includes: a heating means for heating the reaction chamber at a predetermined temperature; a cleaning gas supply means for supplying a cleaning gas containing fluorine and hydrogen fluoride into the reaction chamber; and control means for controlling the component devices of the thin film deposition system; wherein the control means controls the heating means so as to heat the reaction chamber at a temperature in the range of 400° C. to 700° C. and controls the cleaning gas supply means so as to supply the cleaning gas into the reaction chamber after the reaction chamber has been heated at a temperature in the range of 400° C. to 700° C. by the heating means so that the cleaning gas is activated to remove deposits deposited on the inside surface of a reaction tube defining the reaction chamber and surfaces of members placed in the reaction chamber by the activated cleaning gas.

Preferably, the controller controls the cleaning gas supply means so as to supply the cleaning gas into the reaction chamber maintained in a state where the pressure in the reaction chamber is in the range of 13.3 Pa to the normal pressure.

Preferably, at least component members of the thin film deposition system to be exposed to the cleaning gas in the reaction chamber are made of quartz.

A program in a fifth aspect of the present invention to be executed by a computer to control a thin film deposition system, for depositing a thin film on workpieces placed in a reaction chamber by supplying process gases into the reaction chamber, including a heating means for heating the reaction chamber at a predetermined temperature, a cleaning gas supply means for supplying a cleaning gas containing fluorine and hydrogen fluoride into the reaction chamber, and a control means for controlling the heating means so as to heat the reaction chamber at a predetermined temperature and for controlling the cleaning gas supply means so as to supply the cleaning gas into the reaction chamber after the reaction chamber has been heated at the predetermined temperature by the heating means so that the cleaning gas is activated to remove deposits containing tetraethoxysilane and deposited on surfaces of component members placed in the reaction chamber by the activated cleaning gas.

A program in a sixth aspect of the present invention to be executed by a computer to control a thin film deposition system, for depositing a thin film on workpieces placed in a reaction chamber by supplying process gases into the reaction chamber, including a heating means for heating the reaction chamber at a predetermined temperature, a cleaning gas supply means for supplying a cleaning gas containing fluorine and hydrogen fluoride into the reaction chamber, and a control means for controlling the heating means so as to heat the reaction chamber at a temperature in the range of 400° C. to 700° C. and for controlling the cleaning gas supply means so as to supply the cleaning gas into the reaction chamber after the reaction chamber has been heated at a temperature in the range of 400° C. to 700° C. by the heating means so that the cleaning gas is activated to remove deposits deposited on surfaces of component members placed in the reaction chamber by the activated cleaning gas.

Preferably, the control means controls the cleaning gas supply means so as to supply the cleaning gas into the reaction chamber with the reaction chamber maintained at a pressure in the range of 13.3 Pa to the normal pressure.

Preferably, at least component members to be exposed to the cleaning gas in the reaction chamber are made of quartz.

The present invention is capable of efficiently removing reaction products deposited on surfaces component members of the thin film deposition system.

### BRIEF DESCRIPTION OF THE DRAWINGS

FIG. 1 is a longitudinal sectional view of a thermal processing system in a preferred embodiment according to the present invention;

FIG. 2 is a block diagram of a controller included in the thermal processing system shown in FIG. 1;

FIG. 3 is a diagrammatic view of a film forming recipe;

FIG. 4 is a diagrammatic view of a cleaning recipe;

FIG. 5 is a table of cleaning conditions for a cleaning process;

FIG. 6 is a graph showing etch rates at which TEOS and quartz are etched under the cleaning conditions shown in FIG. 5; and

FIG. 7 is a graph showing selectivities under the conditions shown in FIG. 5.

### BEST MODE FOR CARRYING OUT THE INVENTION

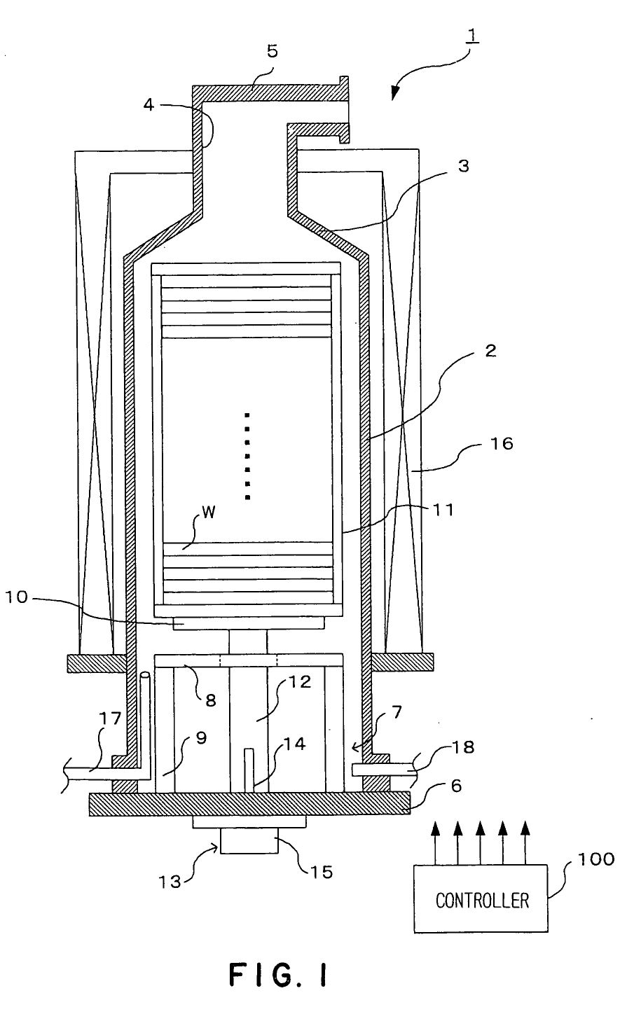

A method of cleaning a thin film deposition system, a thin film deposition system and a program embodying the present invention will be described with reference to the accompanying drawings. The present invention will be described as applied to a batch type vertical thermal processing system 1 shown in FIG. 1.

Referring to FIG. 1, the vertical thermal processing system 1 has a substantially cylindrical reaction tube 2 installed with its longitudinal axis set upright. The reaction tube 2 is made of a material excellent in heat resistance and corrosion resistance, such as quartz.

An upper end part of the reaction tube 2 is converged upward to form a top part 3 having a shape substantially resembling a circular cone. An exhaust opening 4 through which gases are discharged from the reaction tube 2 is formed in a central part of the top part 3. An exhaust pipe 5 is connected hermetically to the exhaust opening 4. The exhaust pipe 5 is provided with a pressure adjusting mechanism including a valve, not shown, and a vacuum pump 127. The pressure adjusting mechanism adjusts the pressure in the reaction tube 2 to a desired pressure (a desired vacuum).

A lid 6 is disposed below the reaction tube 2. The lid 6 is made of a material excellent in heat resistance and corrosion resistance, such as quartz. The lid 6 is moved vertically by a boat elevator 128. The boat elevator 128 raises the lid 6 to close the open lower end (furnace entrance) of the reaction tube 2. The boat elevator 128 lowers the lid 6 to open the open lower end of the reaction tube 2.

A heat-insulating cylinder 7 is mounted on the lid 6. The heat-insulating cylinder 7 includes, as principal components, a flat resistance heater 8 for preventing the drop of the temperature in the reaction tube 2 due to dissipation of heat through the furnace entrance of the reaction tube 2, and a cylindrical support member 9 supporting the heater 8 at a predetermined height from the lid 6.

A rotating table 10 is disposed above the heat-insulating cylinder 7. The rotating table 10 supports a wafer boat 11 holding semiconductor wafers W thereon to rotate the wafer boat 11. More specifically, the rotating table 10 is supported on a rotating shaft 12 extending through a central part of the heater 8 and linked to a rotating mechanism 13 for rotating the rotating table 10. The rotating mechanism 13 includes, as principal components, a motor, now shown, and a rotative transmission 15 having a rotating drive shaft 14. The rotating drive shaft 14 is passed upward through the lid 6 and is connected to the rotating shaft 12 of the rotating table 10. The gap between the drive shaft 14 and the lid 6 is sealed. The torque of the motor is transmitted through the rotating shaft 12 t the rotating table 10. When the motor of the rotating mechanism 13 drives the drive shaft 14, the drive shaft 14 drives the rotating shaft 12 to rotate the rotating table 10.

The wafer boat 11 is capable of holding a plurality of semiconductor wafers W, for example, one hundred semiconductor wafers W, at predetermined vertical intervals. The wafer boat 11 is made of, for example, quartz. The wafer boat 11 holding the semiconductor wafers W and mounted on the rotating table 10 rotates together with the rotating table 10.

A reactor heater 16 having a resistance heating element surrounds the reaction tube 2. The reactor heater 16 heats the interior of the reaction tube 2 at a predetermined temperature to heat the semiconductor wafers W at a predetermined temperature.

A process gas supply pipe 17 for carrying process gases, such as source gases and a cleaning gas, is connected to a lower end part of the reaction tube 2. The process gas supply pipe 17 is connected through mass flow controllers (MFCs) 125 to process gas sources, not shown. A tetraethoxysilane film (TEOS film) (CVD oxide film), is to be deposited on the wafers W, TEOS is used as a source gas. The cleaning gas is capable of removing deposits adhering to the inside surfaces of the thermal processing system 1. The cleaning gas is, for example a gas containing fluorine (F₂) and hydrogen fluoride (HF). Practically, a plurality of process gas supply pipes 17 are connected to the reaction tube 2 to carry different gases, respectively, into the reaction tube 2. Only one of the process gas supply pipes 17 is shown in FIG. 1. More concretely, the process gas supply pipes 17 connected to the lower end part of the reaction tube 2 are those for carrying the source gases into the reaction tube 2 and that for carrying the cleaning gas into the reaction tube 2.

A purge gas supply pipe 18 is connected to a lower end part of the reaction tube 2. The purge gas supply pipe 18 is connected through an MFC 125 to a purge gas source, not shown to supply a desired purge gas into the reaction tube 2.

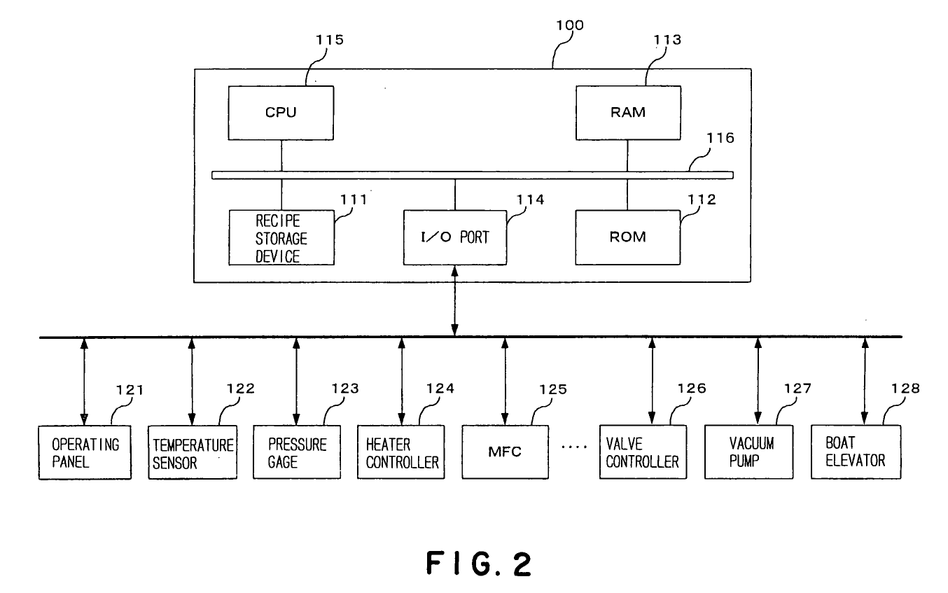

The thermal processing system 1 includes a controller 100 shown in FIG. 2 for controlling the component elements of the thermal processing system 1. Referring to FIG. 2, an operation panel 121, temperature sensors 122, pressure gages 123, a heater controller 124, the MFCs 125, valve controllers 126, the vacuum pump 127 and the boat elevator 128 are connected to the controller 100.

The operation panel 121 is provided with a display and operating buttons. The operator operates the operation panel 121 to give instructions to o the controller 100. The display displays a variety of pieces of information provided by the controller 100.

The temperature sensors 122 measures temperatures in the reaction tube 2 and the exhaust pipe 5 and gives temperature signals representing measured temperatures to the controller 100.

The heater controller 124 controls the heater 8 and the reactor heater 16 individually. The heater controller 124 supplies power to the heater 8 and the reactor heater 16 in response to instructions give thereto by the controller 100 to energize the heater 8 and the reactor heater 16. The heater controller 124 measures the respective power consumptions of the heater 8 and the reactor heater 16 and gives signals representing measured power consumptions to the controller 100.

The MFCs 125 are placed in the process gas supply pipes 17 and the purge gas supply pipe 18, respectively. The MFCs 125 regulate the flow rates of the gases flowing through the corresponding gas supply pipes 17 and 18 so that the gases flow at predetermined flow rates, respectively. The MFCs 125 measure the actually flowing through the corresponding gas supply pipes 17 and 18 and give signals representing measured flow rates to the controller 100.

The valve controllers 126 control the respective openings of the valves placed in the pipes to adjust the openings to those specified by the controller 100. The vacuum pump 127 connected to the exhaust pipe 5 evacuates the reaction tube 2.

The boat elevator 128 lifts up the lid 6 to load the wafer boat 11 holding the semiconductor wafers W and mounted on the rotating table 10 into the reaction tube 2. The boat elevator 128 moves down the lid 6 to unload the wafer boat 11 holding the semiconductor wafers W and mounted on the rotating table 10 from the reaction tube 2.

The controller 100 includes a recipe storage device 111, a ROM 112, a RAM 113, an I/O port 114, a CPU 115 and a bus 116 interconnecting those components of the controller 100.

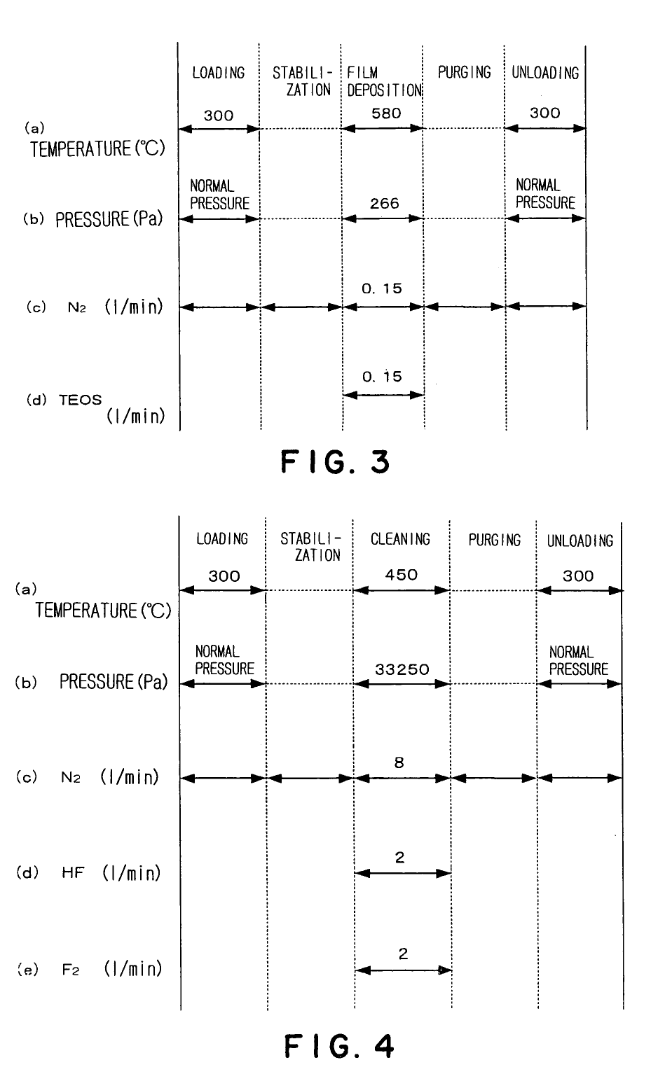

The recipe storage device 111 stores a setup recipe and a plurality of process recipes. The recipe storage device 111 of the thermal processing system 1 as manufactured stores only the setup recipe. The setup recipe is executed to produce thermal models respectively for thermal processing systems. The process recipes define thermal processes to be carried out by the user. For example, the process recipe specifies temperatures and pressures in the reaction tube 2, timing of starting and stopping the supply of the process gases and flow rates of the process gases in periods between the loading of the semiconductor wafers W into and unloading of the semiconductor wafers W from the reaction tube 2 as shown in FIG. 3.

The ROM 112 is an EEPROM, a flash memory or a hard disk. The ROM 112 stores operation programs to be executed by the CPU 115. The RAM 113 serves as a work area for the CPU 115.

The I/O port 114 is connected to the operation panel 121, the temperature sensors 122, the pressure gages 123, the heater controller 124, the MFCs 125, the valve controllers 126, the vacuum pump 127 and the boat elevator 128 to transfer data and signals.

The CPU (central processing unit) 115 is a principal component of the controller 100. The CPU 100 executes the programs stored in the ROM 112 and controls the operations of the thermal processing system 1 according to the process recipes stored in the recipe storage device 111 in response to instructions provided by operating the operation panel 121. The CPU 115 receives measured temperatures in the reaction tube 2 and the exhaust pipe 5 measured by the temperature sensors 122, measured pressures in the reaction tube 2 and the exhaust pipe 5 measured by the pressure gages 123 and measured flow rates of gases measured by the MFCs 125, produces control signals on the basis of the measured data and gives the control signals to the heater controller 124, the MFCs 125, the valve controller 126 and the vacuum pump 127 to make those components of the thermal processing system 1 operate according to the process recipe.

The bus 116 transmits information to the components of the controller 100.

A cleaning method to be executed by the thermal processing system 1 will be described. The cleaning method will be described with reference to a recipe shown in FIG. 4 as applied to removing TEOS deposited on parts of the thermal processing system 1 during the deposition of a TEOS film (CVD oxide film) on semiconductor wafers W by the thermal processing system 1 using tetraethoxysilane (TEOS) as a source gas. A film deposition process for depositing a TEOS film on semiconductor wafers W will be also described. In the following description, the controller 100 (CPU 115) controls the operations of the components of the thermal processing system 1. The controller 100 (CPU 115) controls the heater controller 124 for controlling the heater 8 and the reactor heater 16, the MFCs 125 placed in the process gas supply pipes 17 and the purge gas supply pipe 18, the valve controllers 126 and the vacuum pump 127 so that temperatures, pressures and flow rates in the reaction tube 2 vary in conformity to conditions specified by the recipes.

The film deposition process will be described with reference to the recipe shown in FIG. 3.

The reactor heater 16 heats the interior of the reaction tube 2 at a predetermined loading temperature of, for example, 300° C. as shown in FIG. 3(a). First, a loading step is executed. Nitrogen gas (N₂) is supplied at a predetermined flow rate through the purge gas supply pipe 18 into the reaction tube 2. Subsequently, the wafer boat 11 holding semiconductor wavers W is placed on the rotating table 10, and then the boat elevator 128 lifts up the lid 6 to load the wafer boat 11 into the reaction tube 2. Thus the semiconductor wafers W are contained in the reaction tube 2 and the reaction tube 2 is sealed to complete the loading step.

Then, a stabilization step is executed. Nitrogen gas is supplied at a predetermined flow rate through the purge gas supply pipe 18 into the reaction tube 2 and the reactor heater 16 heats the interior of the reaction tube 2 at a predetermined film deposition temperature (processing temperature) of, for example, 580° C. as shown in FIG. 3(a) The reaction tube 2 is evacuated to a predetermined pressure of, for example, 266 Pa (2 Torr) as shown in FIG. 3(b). The heating and evacuating operations are continued until the interior of the reaction tube 2 is stabilized at the predetermined temperature and the predetermined pressure.

The motor of the rotating mechanism 13 is controlled to rotate the rotating table 10 together with the wafer boat 11 holding the semiconductor wafers W. Consequently, the semiconductor wafers W are heated uniformly.

Then, a film deposition step is executed. After the interior of the reaction tube 2 has been stabilized at the predetermined temperature and the predetermined pressure, the supply of nitrogen gas through the purge gas supply pipe 15 into the reaction tube 2 is stopped, and TEOS as a source gas and nitrogen gas as a diluent gas are supplied into the reaction tube 2 at, for example, 0.15 l/min and 0.15 l/min, respectively, as shown in FIG. 3(c). Thus a TEOS film is deposited on the surfaces of the semiconductor wafers W.

Then, a purging step is executed. After a TEOS film of a predetermined thickness has been formed on the surfaces of the semiconductor wafers W, the supply of TEOS and nitrogen gas through the source gas supply pipes 17 is stopped. Gases remaining in the reaction tube 2 are discharged and nitrogen gas is supplied at a predetermined flow rate through the purge gas supply pipe 18 into the reaction tube 2 to discharge the gases remaining in the reaction tube 2 through the exhaust pipe 5. It is preferable to repeat the purging step including a cycle of discharging the gases from the reaction tube 2 and a cycle of supplying nitrogen gas into the reaction tube 2 several times to purge the reaction tube 2 completely of the gases remaining in the reaction tube.

Subsequently, an unloading step is executed. The reactor heater 16 heats the interior of the reaction tube 2 at a predetermined temperature of, for example, 300° C. as shown in FIG. 3(a) and nitrogen gas is supplied at a predetermined flow rate into the reaction tube 2 to set the interior of the reaction tube 2 at the normal pressure as shown in FIG. 3(b). Then, the boat elevator 128 lowers the lid 6 to unload the wafer boat 11 from the reaction tube 2.

After the film deposition process has been performed several cycles, TEOS deposits not only on the surfaces of semiconductor wafers W, but also on the inside surface of the reaction tube 2. The thermal processing system 1 is cleaned by the cleaning method after the film deposition process has been performed by a predetermined number of cycles. The cleaning method will be described with reference to the recipe shown in FIG. 4.

First, a loading step is executed. The reactor heater 16 heats the interior of the reaction tube 2 at a predetermined loading temperature of, for example 300° C. as shown in FIG. 4(a). Nitrogen gas is supplied at a predetermined flow rate through the purge gas supply pipe 18 into the reaction tube 2. Then, The empty wafer boat 11 not holding any semiconductor wafers W is mounted on the lid 6 and the boat elevator 126 lifts up the lid 6 to load the wafer boat 11 into the reaction tube 2.

Then, a stabilization step is executed. Nitrogen gas is supplied at a predetermined flow rate through the purge gas supply pipe 18 into the reaction tube 2 and the reactor heater 16 heats the interior of the reaction tube 2 at a predetermined cleaning temperature of, for example, 450° C. as shown in FIG. 4(a) The reaction tube 2 is evacuated to a predetermined pressure of, for example, 33,250 Pa (250 Torr) as shown in FIG. 4(b). The heating and evacuating operations are continued until the interior of the reaction tube 2 is stabilized at the predetermined temperature and the predetermined pressure.

Subsequently, a cleaning step is executed. After the interior of the reaction tube 2 has been stabilized at the predetermined temperature and the predetermined pressure, a cleaning gas is supplied into the reaction tube 2. The cleaning gas is produced by mixing hydrogen fluoride (HF) supplied at a predetermined flow rate of, for example, 2 l/min as shown in FIG. 4(d), fluorine gas (F₂) supplied at a predetermined flow rate of, for example 2 l/min as shown in FIG. 4(e) and nitrogen gas as a diluent gas supplied at, for example 8 l/min as shown in FIG. 4(c). Activated fluorine etches off TEOS deposited on the inside surface of the reaction tube 2 and the surface of the wafer boat 11.

Preferably, the temperature of the interior of the reaction tube 2 during the cleaning step is in the range of 400° C. to 700° C. Etch rate at which TEOS is etched is low, TEOS cannot be efficiently etched and the reaction tube 2 and the wafer boat 11 made of quartz are etched at high etch rates if the temperature of the interior of the reaction tube 2 is below 400° C. Thus TEOS selectivity decreases if the temperature of the interior of the reaction tube 2 is below 400° C. If the temperature of the interior of the reaction tube 2 is higher than 700° C., it is possible that the components of the thermal processing system 1 including the exhaust pipe 5 are corroded.

It is preferable that the temperature of the interior of the reaction tube 2 is in the range of 400° C. to 500° C. When the temperature of the interior of the reaction tube 2 is in the range of 400° C. to 500° C., TEOS can be etched at a high etch rate, selectivity with respect to TEOS is high and TEOS can be uniformly etched. When the temperature of the interior of the reaction tube 2 is in the range of 425° C. to 475° C., TEOS can be etched at a very high etch rate, selectivity with respect to TEOS increases and TEOS can be more uniformly etched. The cleaning method in this embodiment heats the interior of the reaction tube 2 at 450° C. as shown in FIG. 4(a).

The interior of the reaction tube 2 is heated at temperatures in the foregoing temperature range and does not need to be heated at a low temperature of 100° C. or below. Therefore, the adjustment of the temperature of the interior of the reaction tube 2 to a desired temperature can be achieved in a short time.

It is desirable that the pressure in the reaction tube 2 during the cleaning step is in the range of 13.3 Pa (0.1 Torr) and the normal pressure. Preferably, the pressure in the reaction tube 2 during the cleaning step is in the range of 20,000 Pa (150 Torr) to 53,200 Pa (400 Torr). When the pressure is in such a preferable pressure range, the etch rate and the selectivity increases and etch uniformity is improved. When the pressure in the reaction tube 2 is in the range of 33,250 Pa (250 Torr) to 53,200 Pa (400 Torr), the etch rate and the selectivity increases and etch uniformity is improved. The cleaning method in this embodiment adjusts the pressure in the reaction tube 2 to 33,250 Pa (250 Torr) as shown in FIG. 4(b).

Then, a purging step is executed. After TEOS deposited on the inside surfaces of the thermal processing system 1 has been removed, the supply of the cleaning gas through the source gas supply pipe 17 is stopped. Gases remaining in the reaction tube 2 are discharged and nitrogen gas is supplied at a predetermined flow rate through the purge gas supply pipe 18 into the reaction tube 2 to discharge the gases remaining in the reaction tube 2 through the exhaust pipe 5.

Subsequently, an unloading step is executed. Nitrogen gas is supplied at a predetermined flow rate through the purge gas supply pipe 18 into the reaction tube 2 to set the interior of the reaction tube 2 at the normal pressure as shown in FIG. 4(b). The reactor heater 16 heats the interior of the reaction tube 2 at a predetermined temperature of, for example, 300° C. as shown in FIG. 4(a). Then, the boat elevator 128 lowers the lid 6 to unload the wafer boat 11 from the reaction tube 2.

After the thermal processing system 1 has been cleaned by the cleaning method, the boat elevator 128 lowers the lid 6, the wafer boat 11 holding semiconductor wafers W is mounted on the lid 6, and then the lid 6 is lifted up to load the wafer boat 11 holding the semiconductor wafers W into the reaction tube 2. Then, the film deposition process is carried out to deposit a TEOS film on the surfaces of the semiconductor wafers W.

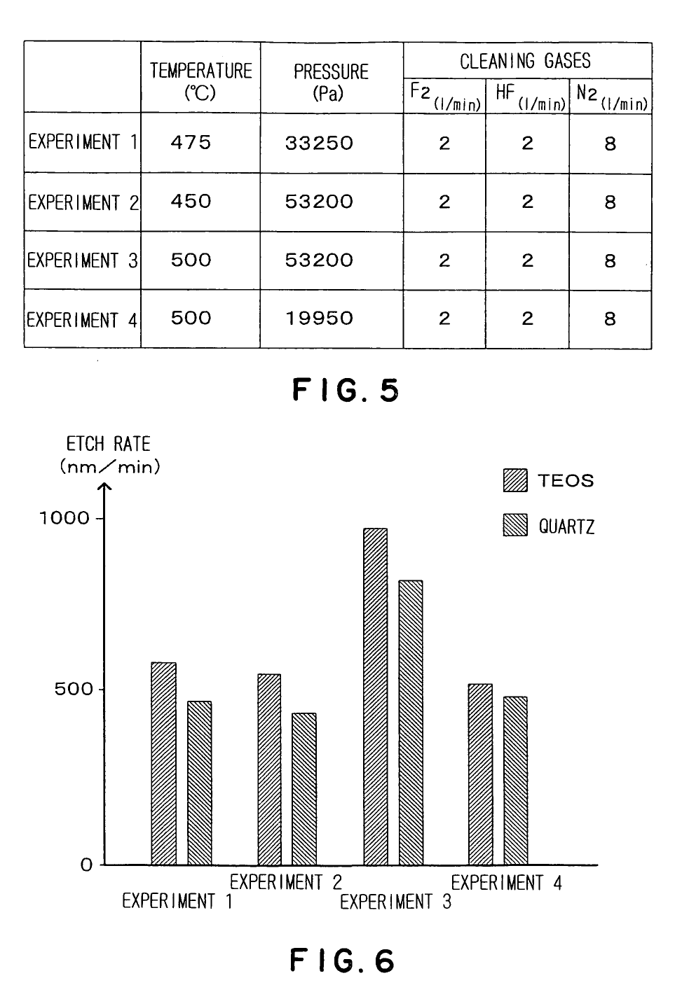

Experiments were conducted to see if TEOS deposited on the inside surfaces of the thermal processing system 1 could have been completely removed by the cleaning method. More specifically, the interior of the reaction tube 2 was heated at different temperatures and the interior of the reaction tube 2 was set at different pressures in the cleaning step as shown in FIG. 5 to execute the cleaning step under different cleaning conditions. TEOS and quartz etch rates at which TEOS and quartz forming the reaction tube 2 were etched, respectively, were measured and selectivity of TEOS to quartz defined by the ratio of the TEOS etch rate to the quartz etch rate was calculated.

First test pieces made of quartz and second test pieces each formed by depositing a 4 μm thick TEOS film on a quartz piece were loaded on the wafer boats 11. The wafer boat 11 was loaded into the reaction tube 2. Then, the cleaning gas was supplied into the reaction tube 2 to subject the first and the second test pieces to a cleaning process. TEOS and quartz etch rates were measured and selectivity of TEOS to quartz, namely, TEOS/quartz etch rate ratio, was calculated.

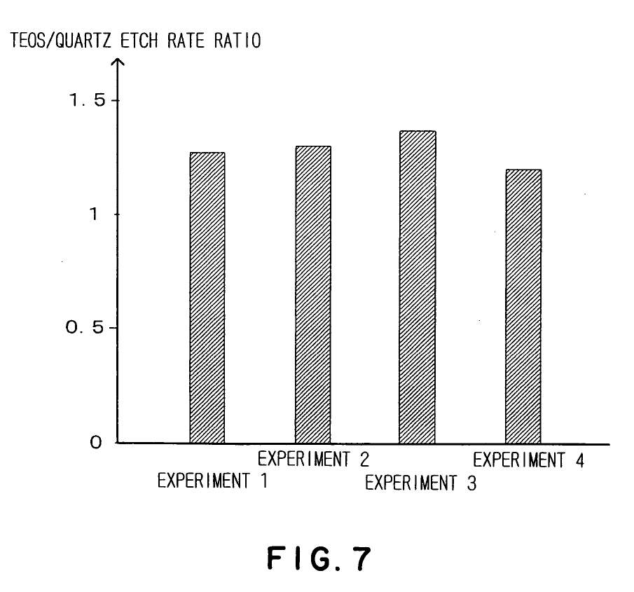

Etch rate was calculated from the difference between the measured weight of the test piece before etching and the measured weight of the same after etching. FIG. 6 shows thus calculated TEOS and quartz etch rates under different cleaning conditions in Experiments 1 to 4 and FIG. 7 shows selectivities of TEOS to quartz under different cleaning conditions in Experiments 1 to 4.

As obvious from FIG. 6, the cleaning conditions for Experiments 1 to 4 are effective in etching TEOS and quartz at satisfactorily high etch rates. As obvious from FIG. 7, the selectivities of TEOS to quartz in Experiments 1 to 4 are not lower than one. Although the selectivity of TEOS to quartz of the cleaning conditions for Experiments 1 to 4 is not sufficiently high, the cleaning conditions may be regarded as effective because the selectivity of TEOS to quartz is not below one.

As apparent from the foregoing description, the cleaning method in this embodiment can remove the reaction product deposited on the inside surfaces of the reaction tube 2 and such by supplying the cleaning gas containing fluorine and hydrogen fluoride into the reaction tube 2. Thus the reaction product deposited on inside surfaces of the component members of the thermal processing system 1 can be efficiently removed and the reduction of the operating ratio of the thermal processing system 1 can suppressed.

The cleaning method in this embodiment that heats the interior of the reaction tube 2 at a temperature in the range of 400° C. to 700° C. can etch TEOS at a high etch rate and can efficiently remove TEOS.

Since the cleaning method in this embodiment does not need to decrease the temperature of the interior of the reaction tube 2 to a temperature of 100° C. or below, the temperature of the interior of the reaction tube 2 can be adjusted in a short time. Consequently, TEOS deposited on inside surfaces of the thermal processing system 1 can be efficiently removed and the reduction of the operating ratio of the thermal processing system 1 can be suppressed.

The present invention is not limited to the foregoing embodiment described by way of example. Various modifications and application of the foregoing embodiment are possible. Other possible embodiments of the present invention will be described.

Although the present invention has been described as applied to removing TEOS deposited on the inside surface of the reaction tube 2 during the deposition of a TEOS film on semiconductor wafers W, the present invention is not limited thereto in its practical application. For example, the present invention is applicable to removing deposits deposited on the inside surface of the reaction tube 2 when a laminated film of HCD-silicon nitride film (DCS-SiN film) and a TEOS film or a laminated film of a BTBAS-SiN film and a BTBAS-SiO film. The present invention is capable of efficiently removing a reaction product deposited on the inside surface of the reaction tube 2 when the reaction tube 2 is used for forming such a laminated film.

Although it is supposed that the reaction tube 2 and the lid 6 are made of quartz in the foregoing description of the present invention, the reaction tube 2 and the lid 6 may be made of silicon carbide (SiC). The present invention is capable of efficiently removing a reaction product deposited on the inside surface of the reaction tube 2 made of SiC.

The cleaning method in the foregoing embodiment uses a mixed gas produced by mixing fluorine and hydrogen fluoride as the cleaning gas. The cleaning gas may be any suitable composition provided that the cleaning gas contains fluorine and hydrogen fluoride and is capable of removing deposits deposited on the inside surfaces of the component members of the thermal processing system 1. The fluorine, hydrogen fluoride and nitrogen gas concentrations of the cleaning gas and the flow rate of the cleaning gas may be optionally determined provided that the cleaning gas is able to remove deposits deposited on the inside surfaces of the component members of the thermal processing system 1.

Although cleaning gas used by the cleaning method in the foregoing embodiment contains nitrogen gas as a diluent gas, the cleaning gas does not necessarily contain any diluent gas. Preferably, the cleaning gas contains a diluent gas because a cleaning gas containing a diluent gas facilitates determining cleaning time. Preferably, the diluent gas is an inert gas. Possible diluent gases other than nitrogen gas are helium gas (He), neon gas (Ne), argon gas (Ar).

The thermal processing system in the foregoing embodiment is provided with the process gas supply pipes respectively for the different process gases; the thermal processing system may be provided with four process gas supply pipes 17 respectively for carrying fluorine, hydrogen fluoride, TEOS and nitrogen gas. A plurality of process gas supply pipes 17 for supplying a single process gas may be connected to a lower end part of the reaction tube 2. The process gas supplied through the plurality of process gas supply pipes 17 into the reaction tube 2 can be uniformly distributed in the reaction tube 2.

Although the present invention has been described as applied to the batch type vertical thermal processing system provided with the single-wall reaction tube 2, the present invention is applicable also to a batch type vertical thermal processing system provided with a double-wall reaction tube formed by combining inner and outer tubes. The present invention is applicable also to single wafer processing thermal processing systems. Workpieces are not limited to semiconductor wafers W and may be, for example, glass substrates for LCDs.

The controller 100 of the embodiment of the present invention does not need to be a special controller, but may be a general computer system. For example, the controller 100 can be constructed by installing programs defining the foregoing processes and stored in a recording medium, such as a flexible disk or a CD-ROM, in a general-purpose computer.

The programs may be supplied by any optional means. The programs may be supplied through communication lines, a communication network or a communication system instead of by the predetermined recording medium. The programs may be published by a bulletin board system (BBS) and may be provided in a signal produced by modulating a carrier by the programs. The programs thus obtained are started and are executed similarly to other application programs under the control of an OS to carry out the foregoing process.

1. A thin film deposition system cleaning method of cleaning a thin film deposition system to remove deposits adhering to surfaces of the component members of the thin film deposition system after thin films have been deposited on workpieces by supplying process gases into a reaction tube included in the thin film deposition system, said thin film deposition system cleaning method comprising a cleaning process including the steps of supplying a cleaning gas containing fluorine and hydrogen fluoride into a reaction chamber defined by the reaction tube and heated at a predetermined temperature, activating the cleaning gas, and removing the deposits by the activated cleaning gas;
wherein the deposits contain tetraethoxysilane.

2. A thin film deposition system cleaning method of cleaning a thin film deposition system to remove deposits adhering to surfaces of the component members of the thin film deposition system after thin films have been deposited on workpieces by supplying process gases into a reaction tube included in the thin film deposition system, said thin film depositing system cleaning method comprising a cleaning process including the steps of supplying a cleaning gas containing fluorine and hydrogen fluoride into a reaction chamber defined by the reaction tube and heated at a predetermined temperature, activating the cleaning gas, and removing the deposits by the activated cleaning gas;
wherein the reaction chamber defined by the reaction tube is heated at a temperature in the range of 400° C. to 700° C. during the cleaning process.

3. The thin film deposition system cleaning method according to claim 1 or 2, wherein the reaction chamber is maintained at a pressure in the range of 13.3 Pa to the normal pressure during the cleaning process.

4. The thin film deposition system cleaning method according to claim 1 or 2, wherein component members of the thin film deposition system placed in the reaction chamber are made of quartz.

5. A thin film deposition system for depositing a thin film on workpieces placed in a reaction chamber by supplying process gases into the reaction chamber, said thin film deposition system comprising:
a heating means for heating the reaction chamber at a predetermined temperature;
a cleaning gas supply means for supplying a cleaning gas containing fluorine and hydrogen fluoride into the reaction chamber; and
a control means for controlling the component devises of the thin film deposition system;
wherein the control means controls the heating means so as to heat the reaction chamber at a predetermined temperature and controls the cleaning gas supply means so as to supply the cleaning gas into the reaction chamber after the reaction chamber has been heated at the predetermined temperature by the heating means so that the cleaning gas is activated to remove deposits containing tetraethoxysilane and deposited on surfaces of the component members of the reaction chamber by the activated cleaning gas.

6. A thin film deposition system for depositing a thin film on workpieces contained in a reaction chamber by supplying process gases into the reaction chamber, said thin film deposition system comprising:
a heating means for heating the reaction chamber at a predetermined temperature;
a cleaning gas supply means for supplying a cleaning gas containing fluorine and hydrogen fluoride into the reaction chamber; and
control means for controlling the component devices of the thin film deposition system;
wherein the control means controls the heating means so as to heat the reaction chamber at a temperature in the range of 400° C. to 700° C. and controls the cleaning gas supply means so as to supply the cleaning gas into the reaction chamber after the reaction chamber has been heated at a temperature in the range of 400° C. to 700° C. by the heating means so that the cleaning gas is activated to remove deposits deposited on surfaces of the component members placed in the reaction chamber by the activated cleaning gas.

7. The thin film deposition system cleaning method according to claim 5 or 6, wherein the controller controls the cleaning gas supply means so as to supply the cleaning gas into the reaction chamber maintained in a state where the pressure in the reaction chamber is in the range of 13.3 Pa to the normal pressure.

8. The thin film deposition system cleaning method according to claim 5 or 6, wherein at least component members of the thin film deposition system to be exposed to the cleaning gas in the reaction chamber are made of quartz.

9. A program to be executed by a computer to control a thin film deposition system, for depositing a thin film on workpieces placed in a reaction chamber by supplying process gases into the reaction chamber, including a heating means for heating the reaction chamber at a predetermined temperature, a cleaning gas supply means for supplying a cleaning gas containing fluorine and hydrogen fluoride into the reaction chamber, and a control means for controlling the heating means so as to heat the reaction chamber at a predetermined temperature and for controlling the cleaning gas supply means so as to supply the cleaning gas into the reaction chamber after the reaction chamber has been heated at the predetermined temperature by the heating means so that the cleaning gas is activated to remove deposits containing tetraethoxysilane and deposited on surfaces of component members placed in the reaction chamber by the activated cleaning gas.

10. A program to be executed by a computer to control a thin film deposition system, for depositing a thin film on workpieces placed in a reaction chamber by supplying process gases into the reaction chamber, including a heating means for heating the reaction chamber at a predetermined temperature, a cleaning gas supply means for supplying a cleaning gas containing fluorine and hydrogen fluoride into the reaction chamber, and a control means for controlling the heating means so as to heat the reaction chamber at a temperature in the range of 400° C. to 700° C. and for controlling the cleaning gas supply means so as to supply the cleaning gas into the reaction chamber after the reaction chamber has been heated at a temperature in the range of 400° C. to 700° C. by the heating means so that the cleaning gas is activated to remove deposits deposited on surfaces of component members placed in the reaction chamber by the activated cleaning gas.

11. The program according to claim 9 or 10, wherein the control means controls the cleaning gas supply means so as to supply the cleaning gas into the reaction chamber with the reaction chamber maintained at a pressure in the range of 13.3 Pa to the normal pressure.

12. The program according to claim 9 or 10, wherein at least component members to be exposed to the cleaning gas in the reaction chamber are made of quartz.
